(19) United States
(12) Patent Application Publication
(10) Pub. No.: US 2006/0091459 A1
(43) Pub. Date: May 4, 2006

(54) SEMICONDUCTOR DEVICE HAVING METAL SILICIDE AND METHOD OF MAKING THE SAME

(76) Inventor: Nien-Chung Li, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/904,264

(22) Filed: Nov. 1, 2004

(51) Int. Cl. H01L 29/94

(52) U.S. Cl. 257/336; 257/344; 257/382; 257/413

(57) ABSTRACT

A MOS transistor device includes a polysilicon gate with opposing sidewalls over an active area of a semiconductor substrate. The polysilicon gate has a gate length “L”. Dielectric spacers are disposed at a lower portion of the opposing sidewalls of the polysilicon gate. A metal silicide layer is situated approximately a vertical height “H” above a top surface of the dielectric spacers. The metal silicide layer is formed from an upper exposed portion of the polysilicon gate. Most importantly, the vertical height “H” is greater than the gate length “L” (H>L rule). A diffusion region is implanted into the semiconductor substrate and is adjacent to the polysilicon gate.

### BACKGROUND OF INVENTION

1. Field of the Invention

The present invention relates to the field of fabrication of integrated circuits, and, more particularly, to a semiconductor device with metal silicide portions formed therein. The formed metal silicide portions have improved thermal stability. A method for making such semiconductor device is also proposed, which can effectively solve the agglomeration problem.

2. Description of the Prior Art

Field effect transistors represent the most frequently used circuit elements in modern integrated circuits. Typically, a huge number of field effect transistors is simultaneously formed on a substrate and are connected to establish the required functionality of the circuit. Generally, a field effect transistor comprises two highly doped drain and source regions that are embedded in a lightly and inversely doped silicon well region. The drain and the source regions are spaced apart with a channel region interposed, wherein a conductive channel forms between the drain and source regions in the channel region upon application of an appropriate voltage to a polysilicon gate that is usually formed over the channel region and is separated therefrom by a gate oxide layer.

It is known that low resistivity interconnection paths are critical in order to fabricate dense, high performance devices. One approach to reduce the resistivity of the interconnect to less than that exhibited by polysilicon alone is to form a polycide structure consisting of a low resistance metal silicide on top of a doped polysilicon layer.

As the dimensions of a device shrink, the contact resistance of the shallower junctions or diffusion regions also increases. To reduce these resistance values, while simultaneously reducing the interconnect resistance of the polysilicon lines, self-aligned silicide or “salicide” technology is typically employed. Salicide technology involves depositing metal over a MOS structure and reacting exposed silicon areas of the diffusion region as well as exposed polysilicon areas on the gate to form silicides.

However, the device line widths become narrower and the junctions become shallower as the transistor devices become smaller. The shallower junctions limit the thickness of the silicide layer. The thickness of the silicide layer is inversely proportional to the sheet resistance. Thus, a thinner silicide layer means more resistance and a longer RC delay. Further, a so-called agglomeration problem arises when a metal layer such as cobalt reacts at high temperatures with a polysilicon gate having a gate length that is approximately below 50 nm. The agglomeration problem adversely affects the thermal stability of the salicide and therefore the performance of the gate when operating the transistor device.

### SUMMARY OF INVENTION

It is the primary object of the present invention to provide semiconductor devices comprising salicided polysilicon layers with significantly reduced sheet resistance and improved thermal stability.

Another object of this invention is to provide a MOSFET device comprising a salicided polysilicon gate with a feature gate length of about 50 nm or below, and an improved method of eliminating the aforementioned agglomeration problem during the fabrication of such device.

For these purposes, according to one embodiment, the present invention relates to a metal oxide semiconductor (MOS) transistor device. The MOS transistor device includes a polysilicon gate with opposing sidewalls over an active area of a semiconductor substrate. The polysilicon gate has a gate length L. Dielectric spacers are disposed at a lower portions of the opposing sidewalls of the polysilicon gate. A first metal silicide layer is situated approximately a vertical height H above a top surface of the dielectric spacers. The first metal silicide layer is formed from an upper exposed portion of the polysilicon gate and is therefore at the top of the gate. Most importantly, the vertical height H is greater than the gate length L (H>L). A diffusion region is implanted into the semiconductor substrate and is adjacent to the polysilicon gate. A portion of the diffusion region forms a second metal silicide layer. Further, the first metal silicide layer has a thickness that is greater than that of the second metal silicide layer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic cross-sectional diagram illustrating a MOS transistor including a metal silicide layer formed therein in accordance with the present invention; and

FIGS. 2-6 are schematic diagrams demonstrating cross sectional views at various process stages when forming the semiconductor structure in FIG. 1 according to one preferred embodiment of the present invention.

### DETAILED DESCRIPTION

The present invention will now be described with reference to the attached figures. The present invention is understood to be of particular advantage when employed for forming the metal silicide layers of MOS transistor devices. For this reason, examples will be given in the following in which corresponding embodiments of the present invention are utilized for forming the metal silicide layers of a MOS transistor.

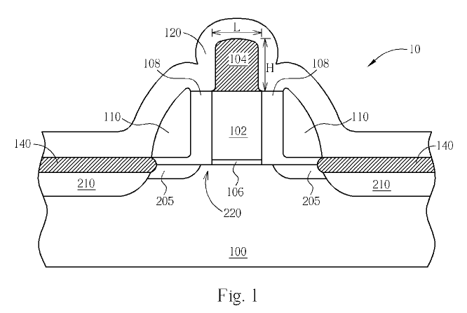

FIG. 1 is a schematic cross-sectional diagram demonstrating a MOS transistor 10 having an improved metal silicide layer 104 formed at top of the polysilicon gate 102 of the MOS transistor in accordance with the present invention. As shown in FIG. 1, the MOS transistor 10 is fabricated on a semiconductor substrate 100. The semiconductor substrate 100 can be either P- or N-type substrate, depending on the type of MOS transistor 10. In another embodiment, the semiconductor substrate 100 may be a silicon-on-insulator (SOI) substrate. It is to be understood that the isolation devices such as shallow trench isolation (STI) or the like, which are specifically employed to insulate the MOS transistor 10, are not shown in the attached figures.

The MOS transistor 10 further comprises source/drain diffusion regions 210 that are heavily doped into the substrate 100 with dopants having a conductivity type that is opposite to that of the substrate 100. Typically, ultra-shallow junction extensions 205, which are contiguous with the heavily doped source/drain diffusion regions 210 and are close to the polysilicon gate 102, are provided. A gate channel 220 is defined between the ultra-shallow junction extensions 205. A gate dielectric layer 106 is formed directly above the gate channel 220. The polysilicon gate 102 is stacked on the gate dielectric layer 106. On the lower portions of the sidewalls of the polysilicon gate 102, a liner spacer 108 and a spacer 110 are formed. A metal silicide layer 140 for reducing contact resistance of the source/drain regions 210 is provided. An optional capping dielectric layer 120 is deposited in a blanket manner to cover the MOS transistor 10.

However, problems arise when polysilicon is used as a gate material, due to its higher resistivity. Furthermore, as stated supra, the agglomeration problem arises when a metal layer such as cobalt reacts at high temperatures with a polysilicon gate having a gate length that is approximately below 50 nm. These problems can be solved by the present invention.

Still referring to FIG. 1, it is the salient feature of the present invention that the MOS transistor 10 comprising a protruding metal silicide layer 104 at the top of the polysilicon gate 102. The metal silicide layer 104 protruding from a reduced top surface of the liner spacer 108 and the spacer 110 has a height denoted as “H” that is greater than the gate length denoted as “L” (i.e., H>L). According to the preferred embodiment of this invention, for a MOS transistor having a gate length of about 55 nm, the height H of the metal silicide layer 104 ranges approximately between 800 and 1,500 angstroms, more preferably about 1,200 angstroms. It is surprisingly found that by following the rule H>L, the prior art agglomeration problem that arises at 50 nm scale devices can be eliminated. The metal silicide layer may comprise cobalt silicide, nickel silicide, titanium silicide, platinum silicide and palladium silicide.

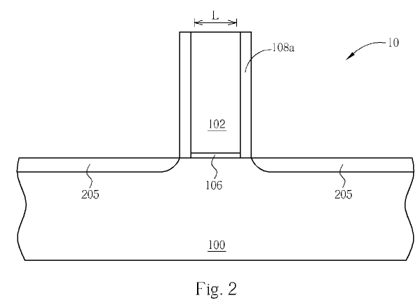

FIGS. 2-6 present a method of forming the semiconductor structure in FIG. 1 in accordance with one preferred embodiment of the present invention. FIG. 2 shows a standard MOS transistor device formed on semiconductor substrate 100 and include polysilicon gate 102 that overlies the gate dielectric layer 106. The polysilicon gate 102 has a gate length L that is about 35 nm to 55 nm, for example, 50 nm. An offset spacer 108a is formed on opposite sidewalls of the polysilicon gate 102. Silicon oxide is used as a material of the offset spacer 108a. Using the polysilicon gate 102 and the offset spacer 108a as a mask, an ion implantation process is then carried out to implant dopants into the substrate 100, thereby forming lightly doped regions 205 at two sides of the polysilicon gate 102. The polysilicon gate 102 may be doped polysilicon.

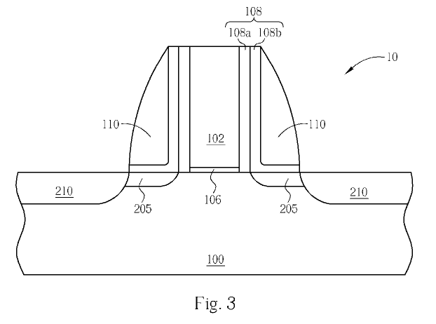

As shown in FIG. 3, an approximately L shaped liner 108b and silicon nitride spacer 110 are formed on sidewalls of the polysilicon gate 102. Process for making the L shaped liner 108b and the silicon nitride spacer 110 includes, for example, depositing a layer of silicon oxide (not shown), followed by the deposition of a conformal layer of silicon nitride (not shown). The formed dielectric layers are etched back in an anisotropic manner to form the spacers. Hereinafter, for the sake of simplicity, the numeral number 108 represents a combined silicon oxide spacer layer consisting of layers 108a and 108b.

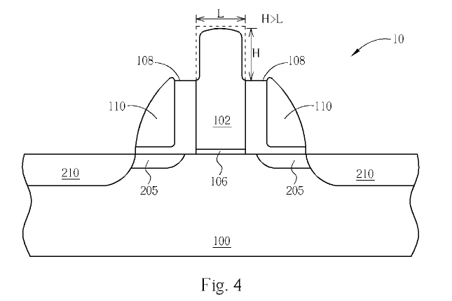

As shown in FIG. 4, the spacer 110 and the spacer layer 108 are simultaneously etched away from the sidewalls of the polysilicon gate 102 selective to the polysilicon gate 102 such that an upper portion of the polysilicon gate 102 including the side portions with a vertical height H (H: distance from the etched top surface of the remaining spacer layer 108 to the uppermost surface of the polysilicon gate 102 after the etch) is exposed. It is worthy noted that during the etch of the spacer 110 and spacer layer 108, the polysilicon gate 102 may be slightly etched and trimmed to a shape that is not rectangular in a cross sectional view, which is specifically indicated in FIG. 4 with dashed line. According to this invention, the vertical height H of the exposed side portions of the polysilicon gate 102 is greater than the gate length L thereof.

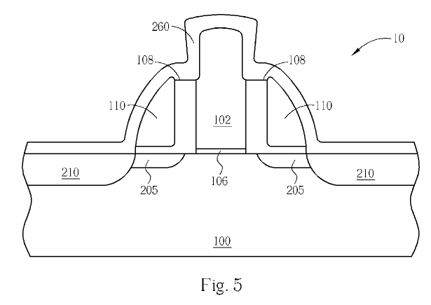

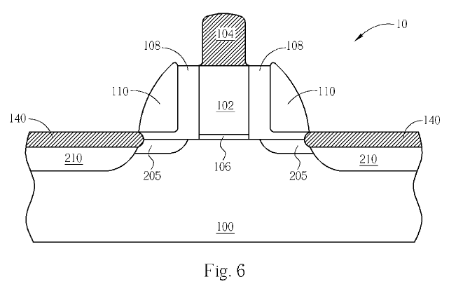

Subsequently, as shown in FIGS. 5 and 6, a self-aligned silicide (salicide) process is carried out. First, as shown in FIG. 5, a layer of metal 260 such as, for example, cobalt, nickel, titanium, platinum, palladium or the like is formed over the substrate 100 in a blanket manner. As shown in FIG. 6, a thermal process is then performed to form silicide layers 104 and 140 in the exposed polysilicon gate 102 and the diffusion regions 210, respectively. The thickness of the silicide layer 104 is at least twice thicker than that of the silicide layer 140. The remaining metal (not shown) is removed. It is unexpected that, as stated supra, the prior art agglomeration problem that arises at 50 nm (gate length) scale or below can be effectively eliminated by following the H>L rule according to this invention.

Those skilled in the art will readily observe that numerous modifications and alterations of the device and method may be made while retaining the teachings of the invention. Accordingly, the above disclosure should be construed as limited only by the metes and bounds of the appended claims.

1. A metal oxide semiconductor (MOS) transistor device comprising:
a polysilicon gate with opposing sidewalls over an active area of a semiconductor substrate, said polysilicon gate having a gate length L that is smaller than 55 nm;
dielectric spacers disposed at a lower portions of said opposing sidewalls of said polysilicon gate;
an upper portion of said polysilicon gate protruding from said dielectric spacers being completely transformed into a first metal silicide layer having approximately a rectangular cross section and a thickness that is approximately equal to a vertical height H from a top surface of said dielectric spacers, wherein said vertical height H is greater than said gate length L (H>L), thereby preventing transformation of said upper portion of said polysilicon gate into said first metal silicide layer from agglomeration; and
a source/drain diffusion region in said semiconductor substrate and adjacent to said polysilicon gate;
a second metal silicide layer on said source/drain diffusion region, wherein said second metal silicide layer is thinner than said first metal silicide layer.

2. The MOS transistor device according to claim 1 wherein said first metal silicide layer comprises cobalt silicide, nickel silicide, titanium silicide, platinum silicide and palladium silicide.

3. The MOS transistor device according to claim 1 wherein said gate length ranges between 35 nm and 55 nm.

4. The MOS transistor device according to claim 1 wherein said vertical height H ranges between 800 and 1,500 angstroms.

5. The MOS transistor device according to claim 1 wherein said gate length L is less than 50 nm.

6. The MOS transistor device according to claim 1 wherein said dielectric spacers on said opposing sidewalls of said polysilicon gate comprises an approximately L shaped liner spacer and a silicon nitride spacer.

7. The MOS transistor device according to claim 6 wherein said dielectric spacers further comprises an offset spacer between said approximately L shaped liner spacer and said sidewall of said polysilicon gate.

8. The MOS transistor device according to claim 1 wherein said source/drain diffusion region is contiguous with a lightly doped extension region that is disposed underneath said dielectric spacer.
